(19) United States
(12) Patent Application Publication
(10) Pub. No.: US 2009/0242129 A1
(43) Pub. Date: Oct. 1, 2009

(54) THERMAL PROCESSING APPARATUS AND PROCESSING SYSTEM

(75) Inventors: Tadashi Onishi, Nirasaki-shi (JP); Shigeki Tozawa, Nirasaki-shi (JP); Yusuke Muraki, Nirasaki-shi (JP); Takafumi Nitoh, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON, LIMITED, Tokyo (JP)

(21) Appl. No.: 12/409,664

(22) Filed: Mar. 24, 2009

Related U.S. Application Data
(60) Provisional application No. 61/109,973, filed on Oct. 31, 2008.

(30) Foreign Application Priority Data
Mar. 27, 2008 (JP) JP2008-083882

(51) Int. Cl. B44C 1/22; C23C 16/46

(52) U.S. Cl. 156/345.37; 118/724; 257/E21.218

(57) ABSTRACT

A heat treatment apparatus for heat-treating a silicon substrate includes a mounting table for mounting and heating the silicon substrate thereon, wherein a cover made of any of silicon, silicon carbide, and aluminum nitride is placed on an upper surface of the mounting table. By covering the upper surface of the mounting table by the cover made of silicon or the like, metal contamination of the lower surface of the silicon substrate is suppressed.

### CROSS REFERENCE TO RELATED APPLICATIONS

The present invention contains subject matter related to Japanese Patent Application No. 2008-083882, filed on Mar. 27, 2008, and Provisional Application No. 61/109,973, filed on Oct. 31, 2008, the entire contents of which being incorporated herein by reference.

### BACKGROUND OF THE INVENTION

1. Field of the Invention

The present invention relates to a heat treatment apparatus for heat-treating a silicon substrate, and a processing system for removing a silicon oxide film formed on an upper surface of the silicon substrate.

2. Description of the Related Art

In manufacturing processes of semiconductor devices, for instance, there has been known a processing system for removing a silicon oxide film existing on a front surface of a semiconductor wafer (hereinafter, referred to as a “wafer”) not by using plasma but by dry-etching (see, Japanese Patent Application Laid-open No. 2007-180418). This processing system includes a COR apparatus for altering a silicon oxide film formed on the upper surface of the wafer into a reaction product film by supplying a mixed gas containing hydrogen fluoride gas and ammonia gas to the upper surface of the wafer, and a heat treatment apparatus for heating the reaction product to vaporize (sublimate) it.

In the heat treatment apparatus in the processing system, a mounting table for mounting and heating the wafer thereon is included, and aluminum (Al) is used as the material of the mounting table because of thermal conductivity, etching proof performance, economic efficiency. Further, the front surface of the mounting table made of aluminum is also anodized because of improvement in etching proof performance and so on.

However, when the wafer is mounted on the mounting table made of aluminum and subjected to heat treatment in the heat treatment apparatus, an aluminum component has transferred to the lower surface of the wafer to cause the metal contamination of the lower surface of the wafer. In this case, a plurality of support pins have also been provided on the upper surface of the mounting table to support the lower surface of the wafer by the support pins, thereby forming a space between the lower surface of the wafer and the upper surface of the mounting table. Further, the present inventors tried to further perform steam sealing for the front surface of the mounting table made of anodized aluminum and to perform also OGF (OUT GAS FREE) processing. However, the metal contamination of the lower surface of the wafer could not be sufficiently suppressed.

Such a metal contamination problem of the wafer lower surface in the heat treatment apparatus prominently occurred when the heating temperature of the wafer was increased. Therefore, conventionally, the metal contamination was suppressed by controlling the heating temperature of the wafer to a lower value. However, if the heating temperature of the wafer is controlled to a lower value, the time required for vaporizing (sublimating) the reaction product to remove it is long, causing a problem of increasing the processing time.

### SUMMARY OF THE INVENTION

The present invention has been developed in view of the above points, and its object is to make it possible to sufficiently suppress metal contamination of a lower surface of a silicon substrate even if the heating temperature in a heat treatment apparatus is increased.

To solve the above-described problem, according to the present invention, a heat treatment apparatus for heat-treating a silicon substrate is provided which includes a mounting table for mounting and heating the silicon substrate thereon, wherein a cover made of any of silicon, silicon carbide, and aluminum nitride is placed on an upper surface of the mounting table. With the heat treatment apparatus, the metal contamination of the lower surface of the silicon substrate can be suppressed by covering the upper surface of the mounting table by the cover made of silicon or the like.

In the heat treatment apparatus, the cover may be, for example, disk-shaped and may have a diameter larger than a diameter of the silicon substrate in a disk shape mounted on the mounting table. Further, a plurality of support pins for supporting a lower surface of the silicon substrate may be provided on an upper surface of the cover. Further, recessed portions for receiving the plural support pins provided on the upper surface of the mounting table may be provided in a lower surface of the cover.

Further, a reaction product film which is made by altering a silicon oxide film by chemical reaction with a mixed gas containing hydrogen fluoride gas and ammonia gas may be formed on an upper surface of the silicon substrate. The processing of altering the silicon oxide film existing on the front surface of the substrate to produce the reaction product here is, for example, COR (Chemical Oxide Removal) processing (chemical oxide removal processing). In the COR processing, gas containing a halogen element and basic gas are supplied as process gases to the Si substrate, thereby causing a chemical reaction of the oxide film on the Si substrate and gas molecules of the process gases so that the reaction product is produced. The gas containing the halogen element is, for example, hydrogen fluoride gas (HF) and the basic gas is, for example, ammonia gas (NH₃). In this case, a reaction product mainly containing ammonium fluosilicate ((NH₄)₂SiF₆) and water (H₂O)) is produced. In the heat treatment apparatus of the present invention, the silicon substrate is heated, whereby the reaction product of ammonium fluosilicate and so on can be vaporized (sublimated) to be removed.

According to the present invention, a processing system for removing a silicon oxide film formed on an upper surface of a silicon substrate is also provided which includes: a COR apparatus for altering a silicon oxide film formed on the upper surface of the silicon substrate into a reaction product film by supplying a mixed gas containing hydrogen fluoride gas and ammonia gas to the upper surface of the silicon substrate; and the above-described heat treatment apparatus.

According to the present invention, the metal contamination of the lower surface of the silicon substrate can be suppressed by covering the upper surface of the mounting table by the cover made of silicon or the like. Further, since the metal contamination of the lower surface of the silicon substrate can be sufficiently suppressed even if the heating temperature is increased, the processing temperature can be increased to reduce the processing time.

### BRIEF DESCRIPTION OF THE DRAWINGS

FIG. 1 is a schematic longitudinal sectional view showing a structure of a front surface of a wafer before etching of a BPSG film is performed;

FIG. 2 is a schematic plan view of a processing system;

FIG. 3 is an explanatory view showing a configuration of a PHT apparatus;

FIG. 4 is a sectional view of a mounting table;

FIG. 5 is a plan view of the mounting table;

FIG. 6 is an explanatory view showing a configuration of a COR apparatus;

FIG. 7 is a schematic longitudinal sectional view showing a state of a wafer after COR processing;

FIG. 8 is a schematic longitudinal sectional view showing a state of the wafer after PHT processing;

FIG. 9 is a schematic longitudinal sectional view showing a state of the wafer after film forming processing;

FIG. 10 is a schematic plan view of a processing system according to another embodiment;

FIG. 11 is a schematic longitudinal sectional view showing a structure of a front surface of a wafer according to another embodiment;

FIG. 12 is a graph showing the aluminum transfer amount to a wafer lower surface according to a comparative example without a cover; and

FIG. 13 is a graph showing the aluminum transfer amount to a wafer lower surface according to an example with a cover.

### DETAILED DESCRIPTION OF THE INVENTION

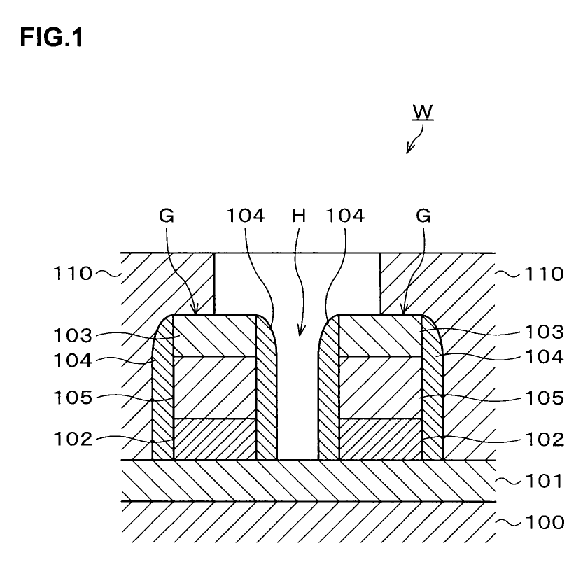

Hereinafter, an embodiment of the present invention will be described. To begin with, a structure of a wafer W that is a silicon substrate to be processed by a processing system 1 according to the embodiment of the present invention will be described. FIG. 1 is a schematic sectional view of the wafer W during the manufacturing process of forming a DRAM (Dynamic Random Access Memory) as a semiconductor device, showing a portion of a front surface (a device formation surface) of the wafer W. The wafer W is a silicon (Si) wafer in the shape of a thin plate formed, for example, in a substantially disk shape, and has a BPSG (Boron-Doped Phosphor Silicate Glass) film 101 that is an insulating film formed on a front surface of a silicon layer 100. The BPSG film 101 is a silicon oxide film (silicon dioxide (SiO₂)) containing boron (B) and phosphor (P). This BPSG film 101 is a CVD silicon oxide film formed on the front surface of the wafer W by the thermal CVD method in a CVD (Chemical Vapor Deposition) apparatus or the like. The BPSG film 101 is the silicon oxide film that is the object of removal processing in the processing system 1.

On an upper surface of the BPSG film 101, gate portions G having gate electrodes are provided side by side. Each of the gate portions G includes a gate electrode 102, a hard mask layer 103 and side wall portions (side walls) 104. The gate electrode 102 is, for example, a Poly-Si (polycrystalline silicon) layer. The gate electrodes 102 are formed side by side on an upper surface of the BPSG film 102. On the upper surface of each of the Poly-Si layers (the gate electrodes 102), for example, a WSi (tungsten silicide) layer 105 is formed. The hard mask layer 103 is made of insulator, for example, SiN (silicon nitride) or the like. The hard mask layer 103 is formed on an upper surface of each of the WSi layers 105. The side wall portion 104 is insulator, for example, a SiN film or the like. The side wall portions 104 are formed to cover both side surfaces of each Poly-Si layer (gate electrode 102), WSi layer 105 and hard mask layer 103, respectively. A lower end portion of the SiN film (the aide wall portion 104) is formed down to a position where it is in contact with the upper surface of the BPSG film 101.

Further, over the BPSG film 101, for example, an HDP-SiO₂ film (a silicon oxide film) 110 is formed to cover the entire BPSG film 101 and gate portions G. This HDP-SiO₂ film 110 is a CVD silicon oxide film (a plasma CVD oxide film) formed using the bias high-density plasma CVD method (the HDP-CVD method), and used as an interlayer insulating film. Note that though both the HDP-SiO₂ film 110 and the BPSG film 101 are CVD oxide films, the HDP-SiO₂ film 110 is a material higher in density and thus harder than the BPSG film 101. In the processing system 1, the HDP-SiO₂ film 110 is not the object of removal processing. A front surface of the HDP-SiO₂ film 110 has no film formed yet and is thus kept exposed.

In the HDP-SiO₂ film 110, a contact hole H is formed between the two gate portions G (between the SiN films (the side wall portions 104) formed at the gate portions G). The contact hole H is formed to penetrate from the upper surface of the HDP-SiO₂ film 110 to the front surface of the BPSG film 101. On the inner sides of the contact hole H, portions of upper surfaces of the hard mask layers 103 of the gate portions G and the SiN films (the side wall portions 104) provided opposite to each other are exposed. At a bottom portion of the contact hole H, the front surface of the BPSG film 101 is exposed. The contact hole H has been formed by selectively (anisotropically) etching the HDP-SiO₂ film 110, for example, by the plasma etching or the like to the SiN films (the side wall portions 104) and the hard mask layers 103.

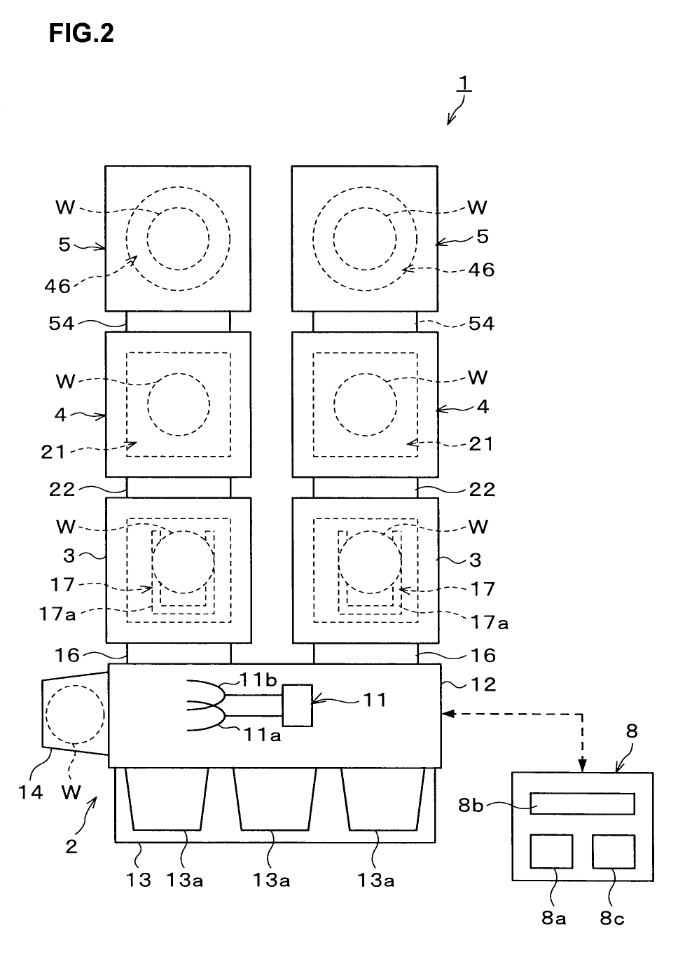

Subsequently, the processing system 1 which performs the etching processing (the removal processing) of the BPSG film 101 exposed at the bottom portion of the contact hole H for the above-described wafer W will be described. The processing system 1 shown in FIG. 2 has a load/unload unit 2 loading/unloading the wafer W to/from the processing system 1, two load lock chambers 3 provided adjacent to the load/unload unit 2, PHT apparatuses 4 as heat treatment apparatuses provided adjacent to the respective load lock chambers 3 for performing a PHT (Post Heat Treatment) processing process as a heating process, COR apparatuses 5 provided adjacent to the respective PHT apparatuses 4 for performing a COR (Chemical Oxide Removal) processing process as an alteration process, and a control computer 8 as a control unit for giving control commands to the units in the processing system 1. The PHT apparatuses 4 and the COR apparatuses 5 which are connected to the load lock chambers 3 respectively are provided side by side in respective lines in this order from the load lock chambers 3.

The load/unload unit 2 has a carrier chamber 12 in which a first wafer carrier mechanism 11 carrying the wafer W in a substantially disk shape is provided. The wafer carrier mechanism 11 has two carrier arms 11a, 11b each holding the wafer W in a substantially horizontal state. On a side of the carrier chamber 12, there are, for example, three carrier mounting tables 13 on which carriers 13a each capable of housing a plurality of wafers W in tiers are mounted. Further, an orienter 14 is placed which rotates the wafer W and optically calculates its eccentricity amount to align the wafer W.

In the load/unload unit 2, the wafer W is held by either of the carrier arms 11a, 11b, and when the wafer carrier mechanism 11 is driven, the wafer W is rotated and moved straight within a substantially horizontal plane or lifted up/down to be carried to a desired position. Namely, by the carrier arms 11a, 11b entering and exiting from the carriers 13a on the mounting tables 13, the orienter 14, and the load lock chambers 3, the wafers W are loaded/unloaded thereto/therefrom.

The load lock chambers 3 are connected to the carrier chambers 12 via gate valves 16 respectively. A second wafer carrier mechanism 17 carrying the wafer W is provided in each of the load lock chambers 3. The wafer carrier mechanism 17 has a carrier arm 17 holding the wafer W in a substantially horizontal state. Further, the inside of the load lock chambers 3 can be evacuated.

In the load lock chamber 3, the wafer W is held by the carrier arm 17a, and when the wafer carrier mechanism 17 is driven, the wafer W is rotated and moved straight within a substantially horizontal plane or lifted up/down to thereby be carried. Then, by the carrier arm 17a entering and exiting from the PHT apparatus 4 which is coupled to the load lock chamber 3 in series, the wafer W is loaded into/unloaded from the PHT apparatus 4. Further, by the carrier arm 17a entering and exiting from the COR apparatus 5 via the PHT apparatus 4, the wafer W is loaded into/unloaded from the COR apparatus 5.

The PHT apparatus 4 includes an airtight chamber 20. The inside of the chamber 20 is an airtight processing space 21 for housing the wafer W therein. Further, though not shown, a load/unload port for loading/unloading the wafer W to/from the processing space 21 is provided, and a gate valve 22 for opening/closing the load/unload port is provided. The processing space 21 is connected to the load lock chamber 3 via the gate valve 22.

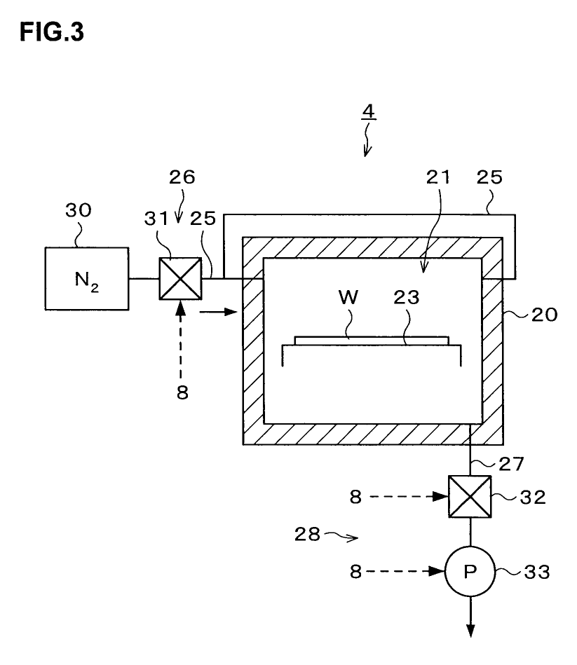

As shown in FIG. 3, in the chamber 20 of the PHT apparatus 4, a mounting table (a PHT mounting table) 23 is provided to have the wafer W mounted thereon in a substantially horizontal state. The mounting table 23 is made of, for example, aluminum (Al), and a front surface of the mounting table 23 has been anodized, for improving the etching proof performance. Further, a gas supply mechanism 26 with a supply path 25 for heating and supplying an inert gas, for example, such as a nitrogen gas (N₂) to the processing space 21, and an exhaust mechanism 28 with an exhaust path 27 for exhausting the processing space 21 are provided. The supply path 25 is connected to a supply source 30 of the nitrogen gas. Further, the supply path 25 is provided with a flow rate regulating valve 31 capable of opening/closing the supply path 25 and adjusting a supply flow rate of the nitrogen gas. The exhaust path 27 is provided with an opening/closing valve 32 and an exhaust pump 33 for forced exhaust.

Note that the operations of units such as the gate valve 22, the flow rate regulating valve 31, the opening/closing valve 32 and the exhaust pump 33 and so on of the PHT apparatus 4 are individually controlled by control commands from the control computer 8. In other words, the supply of the nitrogen gas by the gas supply mechanism 26, the exhaust by the exhaust mechanism 28 and so on are controlled by the control computer 8.

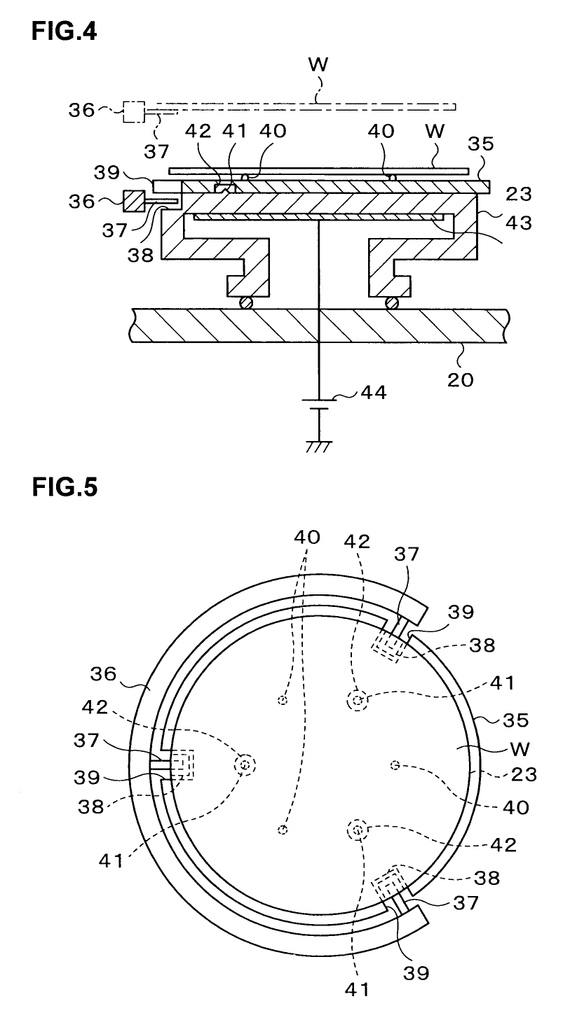

A cover 35 made of silicon (Si) is placed on the upper surface of the mounting table 23 of the PHT apparatus 4 as shown FIGS. 4 and 5 so that the entire upper surface of the mounting table 23 is covered by the cover 35. Therefore, in the state in which the wafer W is mounted on the mounting table 23, the wafer W is mounted on the cover 35 placed on the mounting table 23. The cover 35 is disk-shaped having a thickness of, for example, about 1 mm to about 10 mm and has a diameter larger than that of the wafer W in the disk shape to be mounted on the mounting table 23. For example, when the diameter of the wafer W is about 300 mm (12 inches), the cover 35 has a disk shape having a diameter of about 305 mm to about 310 mm. On the other hand, the upper surface of the mounting table 23 has a diameter that is substantially the same as that of the wafer W, so that when the diameter of the wafer W is about 300 mm (12 inches), the upper surface of the mounting table 23 also has a disk shape having a diameter of about 300 mm. Both of the wafer W and the cover 35 are mounted on the mounting table 23 with their centers aligned with the center of the upper surface of the mounting table 23.

Around the mounting table 23, a wafer lifter mechanism 36 is provided for moving down/up the wafer W to a state in which the wafer W is mounted on the mounting table 23 and to a state in which the wafer W is lifted to above the mounting table 23. To the wafer lifter mechanism 36, support lugs 37 for supporting a lower surface peripheral portion of the wafer W are attached at a plurality of locations. An upper surface peripheral portion of the mounting table 23 is provided with cutout portions 38 for receiving the support lugs 37 at a plurality of locations. In the state where the wafer lifter mechanism 36 moves down so that the wafer W is mounted on the mounting table 23, the plural support lugs 37 are received within the plural cutout portions 38 provided in the upper surface peripheral portion of the mounting table 23 respectively as shown by a solid line in FIG. 4. Further, when the wafer lifter mechanism 36 moves up, the lower surface peripheral portion of the wafer W is supported by the plural support lugs 37 as shown by a one-dotted chain line in FIG. 4, and the wafer W is then lifted to above the mounting table 23. Cutout portions 39 for allowing the support lugs 37 to pass therethrough are provided at a plurality of locations in a peripheral portion of the cover 35, so that when the wafer lifter mechanism 36 moves up/down, the plural support lugs 37 pass through the plural cutout portions 39 respectively.

On the upper surface of the cover 35, support pins 40 are provided at a plurality of locations. Therefore, in the state where the wafer W is mounted on the mounting table 23, the wafer W is mounted on the cover 35 with its lower surface supported by the support pins 40. Note that the support pins 40 on the upper surface of the cover 35 have a height of, for example, about 200 μm.

Further, support pins 41 similar to the support pins 40 provided on the upper surface of the cover 35 are provided also on the upper surface of the mounting table 23 at a plurality of locations. A lower surface of the cover 35 is provided with recessed portions 42 for receiving the support pins 41 on the upper surface of the mounting table 23 at a plurality of locations. Therefore, the lower surface of the cover 35 is in intimate contact with the upper surface of the mounting table 23.

A heater 43 is provided on a rear surface of the mounting table 23. The wafer W mounted on the mounting table 23 is heated by the heater 43. To the heater 43, a DC power source 44 located outside the chamber 20 is connected. The DC power source 44 is controlled by the control command from the control computer 8. Consequently, the heating temperature of the wafer W on the mounting table 23 is controlled by the control computer 8.

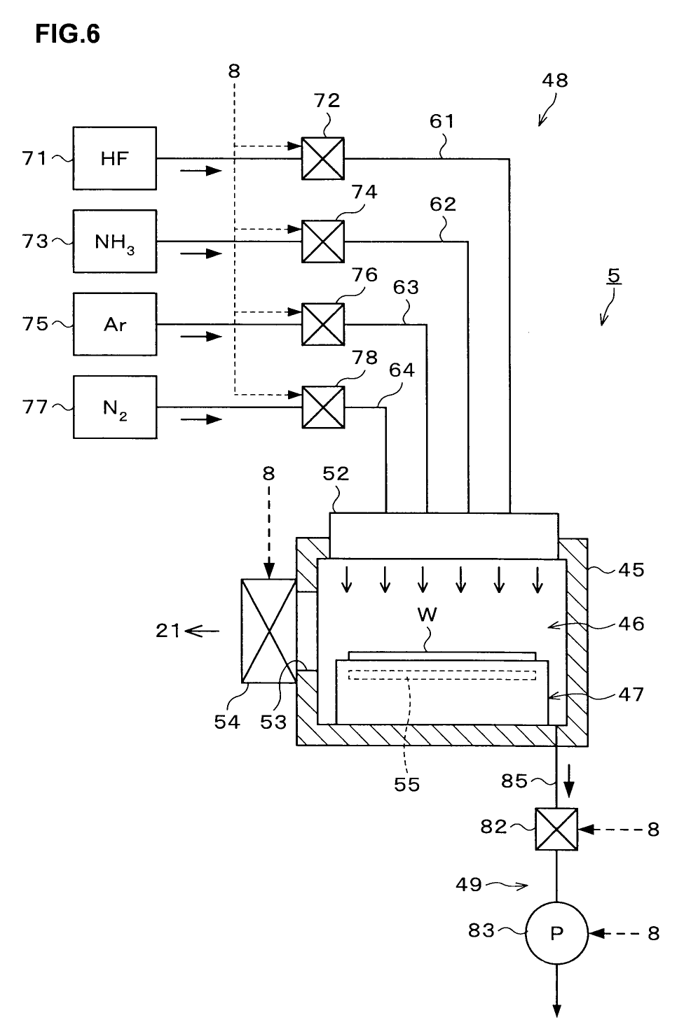

As shown in FIG. 6, the COR apparatus 5 includes an airtight chamber 45. The inside of the chamber 45 is a processing space 46 for housing the wafer W therein. Inside the chamber 45, a mounting table (a COR mounting table) 47 is provided to have the wafer W mounted thereon in a substantially horizontal state. Further, in the COR apparatus 5, a gas supply mechanism 48 for supplying gas into the processing space 46 and an exhaust mechanism 49 for exhausting the inside of the processing space 46 are provided.

A side wall portion of the chamber 45 is provided with a load/unload port 53 for loading/unloading the wafer W to/from the processing space 46, and a gate valve 54 for opening/closing the load/unload port 53. The processing space 46 is connected to the processing space 21 via the gate valve 54. A showerhead 52 is provided in a ceiling portion of the chamber 45 which has a plurality of discharge ports jetting a process gas.

The mounting table 47 forms a substantially circular shape in plan view and secured to a bottom surface of the chamber 45. In the mounting table 47, a temperature adjuster 55 is provided which adjusts the temperature of the mounting table 47. The temperature adjuster 55 includes a pipe through which, for example, liquid for temperature adjustment (for example, water or the like) is circulated. By exchange of heat with the liquid flowing through the pipe, the temperature of the upper surface of the mounting table 47 is adjusted, and by exchange of heat between the mounting table 47 and the wafer W on the mounting table 47, the temperature of the wafer W is adjusted. Note that the temperature adjuster 55 is not limited to the above-described one but may be an electric heater or the like for heating the mounting table 47 and the wafer W, for example, utilizing resistance heat.

The gas supply mechanism 48 includes the above-described showerhead 52, a hydrogen fluoride gas supply path 61 through which hydrogen fluoride gas (HF) is supplied into the processing space 46, an ammonia gas supply path 62 through which ammonia gas (NH₃) is supplied into the processing space 46, an argon gas supply path 63 through which argon gas (Ar) is supplied as inert gas into the processing space 46, and a nitrogen gas supply path 64 through which nitrogen gas (N₂) is supplied as inert gas into the processing space 46. The hydrogen fluoride gas supply path 61, the ammonia gas supply path 62, the argon gas supply path 63, and the nitrogen gas supply path 64 are connected to the showerhead 52. The hydrogen fluoride gas, the ammonia gas, the argon gas, and the nitrogen gas are diffusively jetted through the showerhead 52 into the processing space 46.

The hydrogen fluoride gas supply path 61 is connected to a supply source 71 of the hydrogen fluoride gas. The hydrogen fluoride gas supply path 61 is provided with a flow rate regulating valve 72 capable of opening/closing the hydrogen fluoride gas supply path 61 and adjusting a supply flow rate of the hydrogen fluoride gas. The ammonia gas supply path 62 is connected to a supply source 73 of the ammonia gas. The ammonia gas supply path 62 is provided with a flow rate regulating valve 74 capable of opening/closing the ammonia gas supply path 62 and adjusting a supply flow rate of the ammonia gas. The argon gas supply path 63 is connected to a supply source 75 of the argon gas. The argon gas supply path 63 is provided with a flow rate regulating valve 76 capable of opening/closing the argon gas supply path 63 and adjusting a supply flow rate of the argon gas. The nitrogen gas supply path 64 is connected to a supply source 77 of the nitrogen gas. The nitrogen gas supply path 64 is provided with a flow rate regulating valve 78 capable of opening/closing the nitrogen gas supply path 64 and adjusting a supply flow rate of the nitrogen gas.

The exhaust mechanism 49 includes an exhaust path 85 having an opening/closing valve 82 and an exhaust pump 83 for forced exhaust. An upstream end portion of the exhaust path 85 is opened at a bottom portion of the chamber 45.

Note that the operations of units such as the gate valve 54, the temperature adjuster 55, the flow rate regulating valves 72, 74, 76 and 78, the opening/closing valve 82, the exhaust pump 83 and so on of the COR apparatus 5 are individually controlled by control commands from the control computer 8. In other words, the supply of the hydrogen fluoride gas, the ammonia gas, the argon gas and the nitrogen gas by the gas supply mechanism 48, the exhaust by the exhaust mechanism 49, the temperature adjustment by the temperature adjuster 55 and so on are controlled by the control computer 8.

The functional elements of the processing system 1 are connected via signal lines to the control computer 8 automatically controlling the operation of the whole processing system 1. Here, the functional elements refer to all the elements which operate to realize predetermined process conditions, such as, for example, the aforesaid wafer carrier mechanism 11, wafer carrier mechanisms 17, gate valves 22, flow rate regulating valves 31, exhaust pumps 33, and DC power sources 44 of the PHT apparatuses 4, gate valves 54, temperature adjusters 55, flow rate regulating valves 72, 74, 76 and 78, opening/closing valves 82 and exhaust pumps 83 and so on of the COR apparatuses 5. The control computer 8 is typically a general-purpose computer capable of realizing an arbitrary function depending on software that it executes.

As shown in FIG. 2, the control computer 8 has an arithmetic part 8a including a CPU (central processing unit), an input/output part 8b connected to the arithmetic part 8a, and a recording medium 8c storing control software and inserted in the input/output part 8b. In the recording medium 8c, the control software (program) is recorded which causes the processing system 1 to perform a predetermined substrate processing method to be described later when executed by the control computer 8. By executing the control software, the control computer 8 controls the functional elements of the processing system 1 so that various process conditions (for example, the pressure in the processing space 46 and so on) defined by a predetermined process recipe are realized. In other words, as will be described later in detail, control commands are given so that the COR processing process in the COR apparatus 5 and the PHT processing process in the PHT apparatus 4 are performed in this order.

The recording medium 8c may be the one fixedly provided in the control computer 8, or may be the one removably inserted in a not-shown reader provided in the control computer 8 and readable by the reader. In the most typical embodiment, the recording medium 8c is a hard disk drive in which the control software has been installed by a serviceman of a maker of the processing system 1. In another embodiment, the recording medium 8c is a removable disk such as CD-ROM or DVD-ROM in which the control software is written. Such a removable disk is read by a not-shown optical reader provided in the control computer 8. Further, the recording medium 8c may be either of a RAM (random access memory) type or a ROM (read only memory) type. Further, the recording medium 8c may be a cassette-type ROM. In short, any medium known in a computer technical field is usable as the recording medium 8c. Note that in a factory where the plural processing systems 1 are disposed, the control software may be stored in a management computer centrally controlling the control computers 8 of the processing systems 1. In this case, each of the processing systems 1 is operated by the management computer via a communication line to execute a predetermined process.

Next, the processing of the wafer W in the processing system 1 as configured above will be described. To begin with, wafers W each having contact holes H formed in the HDP-SiO₂ film 110 as shown in FIG. 1 are housed in the carrier 13a and carried to the processing system 1.

In the processing system 1, as shown in FIG. 2, the carrier 13a having plural wafers W housed therein is mounted on the carrier mounting table 13. One of the wafers W is taken out of the carrier 13a by the wafer carrier mechanism 11 and loaded into the load lock chamber 3. When the wafer W is loaded into the load lock chamber 3, the load lock chamber 3 is airtightly closed and pressure-reduced. Thereafter, the gate valves 22 and 54 are opened so that the load lock chamber 3 is made to communicate with the processing space 21 of the PHT apparatus 4 and the processing space 46 of the COR apparatus 5 whose pressures are reduced below the atmospheric pressure. The wafer W is unloaded from the load lock chamber 3 and linearly moved to pass through the load/unload port (not shown) of the processing space 21, the processing space 21 and the load/unload port 53 in this order to be loaded into the processing space 46.

In the processing space 46, the wafer W is delivered, with its device formation surface facing upward, from the carrier arm 17a of the wafer carrier mechanism 17 to the mounting table 47. After the wafer W is loaded, the carrier arm 17a is made to exit from the processing space 46. The load/unload port 53 is closed to airtightly close the processing space 46. Then, the COR processing process is started.

After the processing space 46 is airtightly closed, the ammonia gas, the argon gas and the nitrogen gas are supplied respectively from the ammonia gas supply path 62, the argon gas supply path 63, and the nitrogen gas supply path 64 into the processing chamber 46. Further, the pressure in the processing chamber 46 is brought to a pressure lower than the atmospheric pressure. Further, the temperature of the wafer W on the mounting table 47 is adjusted to a predetermined target value (for example, about 35° C.) by the temperature adjuster 55.

Thereafter, the hydrogen fluoride gas is supplied from the hydrogen fluoride gas supply path 61 into the processing chamber 46. The ammonia gas has been supplied in advance into the processing chamber 46, and therefore by supplying the hydrogen fluoride gas, the atmosphere made in the processing chamber 46 is a processing atmosphere composed of a mixed gas containing the hydrogen fluoride gas and the ammonia gas. By supplying the mixed gas to the front surface of the wafer W in the processing chamber 46, the COR processing is performed on the wafer W.

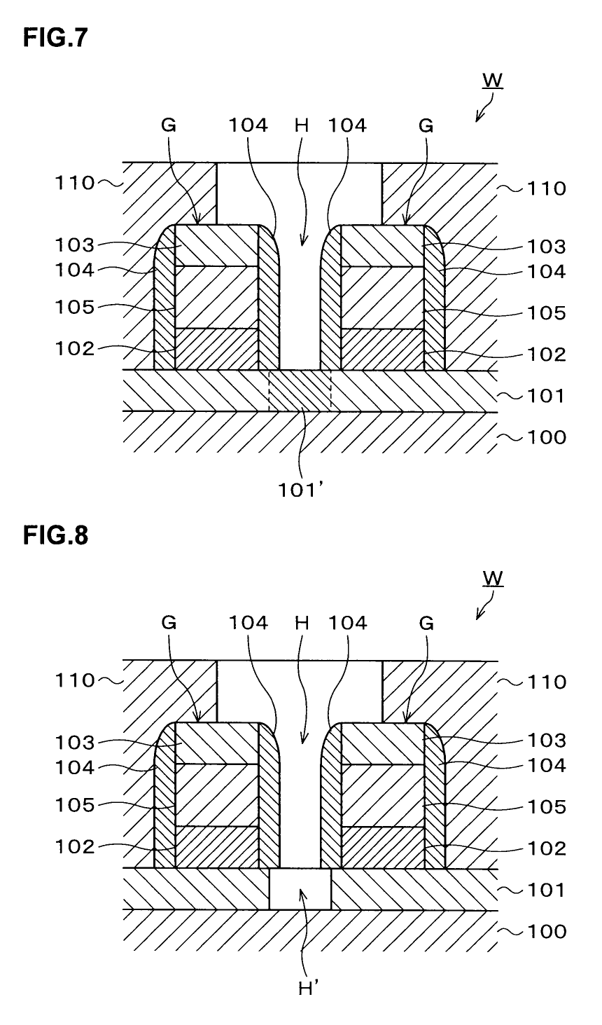

In the low-pressure processing atmosphere in the processing space 46, the BPSG film 101 existing at the bottom portion of the contact hole H on the surface of the wafer W chemically reacts with molecules of the hydrogen fluoride gas and molecules of the ammonia gas in the mixed gas to be altered into a reaction product 101′ (see FIG. 7). As the reaction product 101′, ammonium fluosilicate, water and so on are produced. It should be noted that since this chemical reaction isotropically proceeds, the chemical reaction proceeds from the bottom portion of the contact hole H down to the upper surface of the Si layer and also proceeds from directly below the contact hole H in the lateral direction above the Si layer.

During the COR processing, by adjusting the supply flow rate of each of the process gasses, the supply flow rate of the inert gas, the exhaust flow rate and so on, the pressure of the mixed gas (the processing atmosphere) in the processing space 46 is adjusted to be kept at a fixed pressure (for example, about 80 mTorr (about 10.7 Pa)) that is a pressure reduced below the atmospheric pressure. Further, the partial pressure of the hydrogen fluoride gas in the mixed gas may be adjusted to be about 15 mTorr (about 2.00 P) or higher. Further, as described above, the temperature of the wafer W, that is, the temperature of a portion of the BPSG film 101 which chemically reacts (the temperature of a portion of the BPSG film 101 in contact with the mixed gas (that is, the bottom portion of the contact hole H)) may be kept at a fixed temperature of, for example, about 35° C. or higher. This makes it possible to promote the chemical reaction to increase the production rate of the reaction product 101 ′ to thereby rapidly form a layer of the reaction product 101′. Further, the depth where the chemical reaction becomes saturated (the distance from the front surface of the BPSG film 101 to a position where the chemical reaction stops) can be made sufficiently large. In other words, the chemical reaction is sufficiently performed without interruption until the reaction product 101′ reaches the upper surface of the Si layer 100. Note that the sublimation point of the ammonium fluosilicate in the reaction product 101′ is about 100° C., so that when the temperature of the wafer W is brought to 100° C. or higher, the reaction product 101′ can not be produced in a good condition. Consequently, the temperature of the wafer W is preferably set to be lower than about 100° C.

The above-described depth where the chemical reaction becomes saturated depends on the kind of the silicon oxide film that is the object to be altered (the BPSG film 101 in this embodiment), the temperature of the silicon oxide film (or the temperature of the mixed gas in contact with the silicon oxide film), the partial pressure of the hydrogen fluoride gas in the mixed gas and so on. In other words, by adjusting the temperature of the silicon oxide film and the partial pressure of the hydrogen fluoride gas according to the kind of the silicon oxide film, the depth where the chemical reaction becomes saturated and the production amount of the reaction product 101′ and so on can be controlled, and therefore the etching amount after the PHT processing that will be described later in detail can be controlled. In the case of the BPSG film 101, the depth where the chemical reaction becomes saturated, that is, the etching amount can be made to be about 30 nm (nanometer) or more by adjusting the temperature of the BPSG film 101 to 35° C. or higher and the partial pressure of the hydrogen fluoride gas to about 15 mTorr (about 2.00 Pa) or higher.

Note that the temperature of the wafer W has been set to about 30° C. or lower in the COR processing conventionally generally performed. Further, even when the partial pressure of the hydrogen fluoride gas in the mixed gas is increased, the chemical reaction proceeds only to a certain depth. Therefore, it has been considered that there is a limit in the etching amount by the COR processing, and the etching amount surely etchable by a single COR processing is smaller than about 30 nm, for example, in the BPSG film 101. In contrast, in this embodiment, the temperature of the wafer W is set to about 35° C. or higher that is higher than that in the prior art, and the partial pressure of the hydrogen fluoride gas in the mixed gas is increased to about 15 mTorr (about 2.00 Pa) or higher that is higher than that in the prior art, whereby the depth where the chemical reaction becomes saturated can be increased so that a sufficient amount of alteration can be caused even by a single COR processing.

However, in the COR processing, even the HDP-SiO₂ film 110 formed over the BPSG film 101 can chemically react with the mixed gas. Therefore, the HDP-SiO₂ film 110 can be altered by the COR processing. To suppress the alteration of the HDP-SiO₂ film 110, it is only necessary to bring the partial pressure of the ammonia gas in the mixed gas lower than the partial pressure of the hydrogen fluoride gas. In other words, it is only necessary to set the supply flow amount of the ammonia gas lower than the supply flow rate of the hydrogen fluoride gas. This can prevent the chemical reaction from proceeding while the chemical reaction actively proceeds in the BPSG film 101. In other words, only the BPSG film 101 can be selectively and efficiently altered while the alteration of the HDP-SiO₂ film 110 and the like is being suppressed. Accordingly, damage to the HDP-SiO₂ film 110 can be prevented. As described above, by adjusting the partial pressure of the ammonia gas in the mixed gas, values of the reaction rate of the chemical reaction, the production amount of the reaction product and so on can be made different and thus the etching amounts after the PHT processing described later in detail can be made different between the BPSG film 110 and the HDP-SiO₂ film 110, that is, films that are the same silicon oxide films but different from each other in density, composition, forming method and so on. Note that the chemical reaction when the partial pressure of the ammonia gas is made lower than the partial pressure of the hydrogen fluoride gas is considered not to be reaction rate-determining reaction in which the production rate of the reaction product 101′ is determined by the chemical reaction between the BPSG film 101 and the mixed gas but to be supply rate-determining reaction in which the production rate of the reaction product 101′ is determined by the supply flow rate of the hydrogen fluoride gas.

When the reaction product 101′ is sufficiently formed and the COR processing is finished, the pressure in the processing space 46 is reduced through forced exhaust of the inside thereof. Thus, the hydrogen fluoride gas and the ammonia gas are forcibly exhausted from the processing space 46. When the forced exhaust of the processing space 46 is finished, the load/unload port 53 is opened, and the wafer W is unloaded from the processing space 46 by the wafer carrier mechanism 17 and loaded into the processing space 21 of the PHT apparatus 4. In the above-described manner, the COR processing process is finished.

In the PHT apparatus 4, the wafer W is mounted, with its front surface facing upward, onto the mounting table 23 in the processing space 21. In this case, the wafer W is mounted, with its lower surface supported on the plural support pins 40, onto the cover 35 covering the upper surface of the mounting table 23. Further, as described above, the wafer W has a diameter substantially the same as that of the upper surface of the mounting table 23, whereas the cover 35 has a diameter larger than that of the wafer W. In addition, both the wafer W and the cover 35 are mounted on the mounting table 23 with their centers aligned with the center of the upper surface of the mounting table 23. Therefore, the entire lower surface of the wafer W is completely covered by the cover 35 so that the upper surface of the mounting table 23 is not exposed to the lower surface of the wafer W.

After the wafer W is loaded into processing space 21 of the PHT apparatus 4 in this manner, the carrier arm 17a is made to exit from the processing space 21. Thereafter, the processing space 21 is airtightly closed, and the PHT processing process is started. In the PHT processing, a heating gas at a high temperature is supplied into the processing space 21 to increase the temperature in the processing space 21 while the inside of the processing space 21 is being exhausted. Further, through operation of the heater 43 provided on the rear surface of the mounting table 23, the wafer W mounted on the mounting table 23 is heated. In this case, the support pins 41 on the upper surface of the mounting table 23 are received in the recessed portions 42 provided in the lower surface of the cover 35 such that the lower surface of the cover 35 is intimate contact with the upper surface of the mounting table 23. Thus, the heat of the heater 43 is efficiently transferred to the wafer W via the upper surface of the mounting table 23 and the cover 35. In this case, the thickness of the cover 35 is made, for example, about 1 mm to about 10 mm and the height of the support pins 40 on the upper surface of the cover 35 is made, for example, about 200 μm, thereby allowing the heat to be efficiently transferred from the upper surface of the mounting table 23 to the wafer W.

Thus, the reaction product 101′ produced by the above-described COR processing is heated and vaporized, and is exhausted from below the contact hole H through the contact hole H to the outside of the HDP-SiO₂ film (the outside of the wafer W). In other words, the reaction product 101′ is removed from the BPSG film 101, whereby a space H′ communicating with the bottom portion of the contact hole H is formed on the Si layer 100 as shown in FIG. 8. In this manner, by performing the PHT processing after the COR processing, the reaction product 101′ is removed, so that the BPSG film 101 can be isotropically dry-etched.

By implementing the PHT processing after the COR processing in the above-described manner, the BPSG film 101 can be etched (removed) down to a predetermined depth. Note that since the chemical reaction of the HDP-SiO₂ film 110 that is the silicon oxide film with the mixed gas also occurs slightly in the above-described COR processing, the surface of the HDP-SiO₂ film 110 is altered so that a small amount of reaction product is produced. As described above, however, the BPSG film 101 and the HDP-SiO₂ film 110 are different from each other in the production amount of the reaction product, and therefore the depth to which the reaction product is produced in the HDP-SiO₂ film 110 is much smaller than the depth to which the reaction product 101′ is produced in the BPSG film 101. Therefore, the depth to which the reaction product is removed from the HDP-SiO₂ film 110 by the PHT processing, that is, the etching amount of the HDP-SiO₂ film 110 is suppressed to be an amount much smaller than the etching amount of the BPSG film 110. By adjusting the partial pressure of the ammonia gas in the mixed gas to be lower than the partial pressure of the hydrogen fluoride gas in the COR processing as described above, the etching amount after the PHT processing of each of the silicon oxide films (the BPSG film 101 and the HDP-SiO₂ film 110) can be adjusted. In short, the etching selection ratio can be adjusted. In this embodiment, the etching selection ratio of the BPSG film 101 can be made higher than that of the other structure such as the HDP-SiO₂ film 110 or the like.

When the PHT processing is finished, the supply of the heating gas is stopped and the operation of the heater 43 is stopped, and the load/unload port of the PHT apparatus 4 is opened. Thereafter, the wafer W is unloaded from the processing space 21 by the wafer carrier mechanism 17 and returned into the load lock chamber 3. In the above-described manner, the PHT processing process in the PHT apparatus 4 is finished.

After the wafer W is returned into the load lock chamber 3 and the load lock chamber 3 is airtightly closed, the load lock chamber 3 and the carrier chamber 12 are brought to communicate with each other. Then, the wafer W is unloaded from the load lock chamber 3 by the wafer carrier mechanism 11 and returned into the carrier 13a on the carrier mounting table 13. In the above-described manner, a series of processes in the processing system 1 is finished.

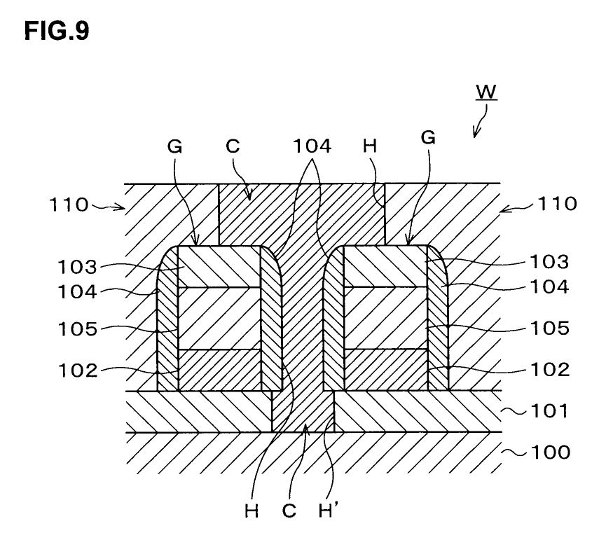

Note that the wafer W for which the etching processing has been finished in the processing system 1 is carried into a film forming apparatus, for example, such as a CVD apparatus or the like in another processing system, in which film forming processing, for example, by the CVD method is performed on the wafer W. In this film forming processing, film formation is performed to fill the contact hole H and the space H′ as shown in FIG. 9. Thus, a capacitor C is formed in the contact hole H and the space H′. The capacitor C is formed to penetrate the HDP-SiO₂ film 110 and the BPSG film 101 between the gate portions G, and a lower end portion of the capacitor C is connected to the upper surface of the Si layer 100 in the space H′.

According to the processing system 1, since the upper surface of the mounting table 23 of the PHT apparatus 4 is covered by the cover 35 made of silicon, transfer of an aluminum component from the upper surface of the mounting table 23 to the lower surface of the wafer W is prevented. Therefore, metal contamination of the wafer lower surface is avoided. Further, since the transfer of the aluminum component from the upper surface of the mounting table 23 to the lower surface of the wafer W is prevented, the heating temperature of the heater 43 can be increased so that the processing temperature of the wafer W in the PHT apparatus 4 can be increased to reduce the processing time.

In the foregoing, a preferred embodiment of the present invention has been described, but the present invention is not limited to such an example. It is obvious that those skilled in the art could think of various modified examples and corrected examples within a range of the technical spirit described in claims, and it is understood that such examples naturally belong to the technical scope of the present invention.

For example, as the material of the cover 35 covering the upper surface of the mounting table 23 of the PHT apparatus 4, silicon carbide (SiC), aluminum nitride (AlN), silicon oxide (SiO₂) and so on can also be used in addition to silicon. However, silicon oxide has a problem of chipping, and aluminum nitride and silicon carbide are expensive. Therefore, silicon is appropriate for the material of the cover 35. Further, the cover 35 made of silicon has the same hardness as that of the wafer W and is thus considered to have little wear due to contact with the lower surface of the wafer W.

Further, the support pins 40 do not need to be provided on the upper surface of the cover 35. Further, the recessed portions 42 in the lower surface of the cover 35 can also be omitted. However, when the support pins 41 are provided on the upper surface of the mounting table 23, it is preferable to provide the recessed portions 42 to bring the lower surface of the cover 35 into intimate contact with the upper surface of the mounting table 23.

The kinds of the gasses to be supplied to the processing space 46 are not limited to the combination of the hydrogen fluoride gas and the ammonia gas. For example, the inert gas supplied to the processing space 46 may be only the argon gas. Further, the inert gas may be another inert gas, for example, any of helium gas (He) and xenon gas, or may be a gas made by mixing two or more kinds of argon gas, nitrogen gas, helium gas, and xenon gas.

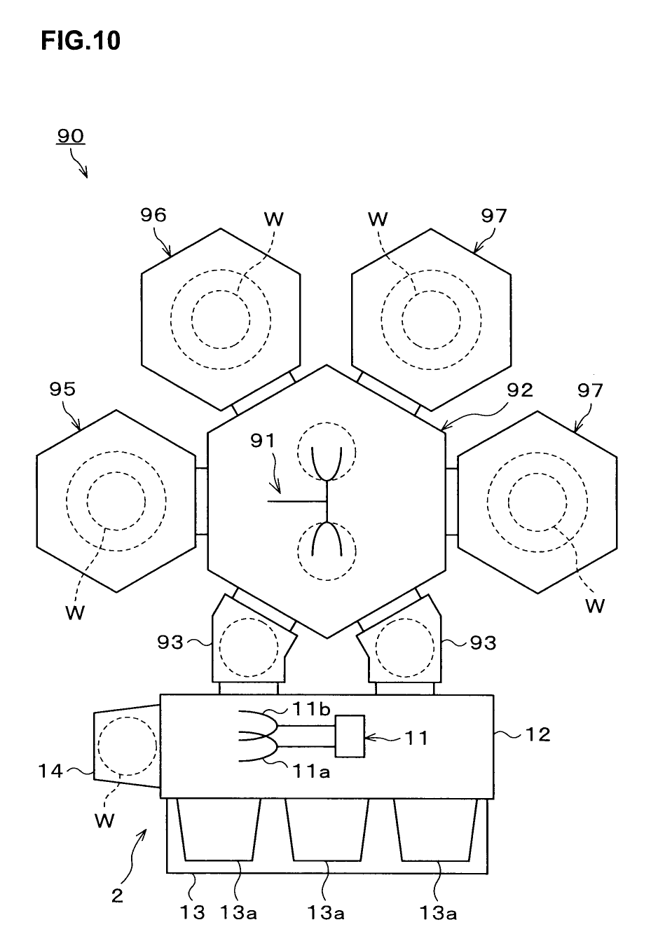

The structure of the processing system 1 is not limited to the one described in the above embodiment. For example, the processing system 1 may be a processing system including a film forming apparatus as well as the COR apparatus and the PHT apparatus. For example, as in a processing system 90 shown in FIG. 10, the configuration may be made such that a common carrier chamber 92 including a wafer carrier mechanism 91 is connected to the carrier chamber 12 via a load lock chamber 93, and a COR apparatus 95, a PHT apparatus 96, a film forming apparatus 97, for example, a CVD apparatus or the like are arranged around the common carrier chamber 92. In this processing system 90, the wafer W is loaded/unloaded by the wafer carrier mechanism 91 to/from the load lock chamber 93, the COR apparatus 95, the PHT apparatus 96, and the film forming apparatus 97. The inside of the common carrier chamber 92 can be evacuated. In other words, by evacuating the inside of the common carrier chamber 92, the wafer W unloaded from the PHT apparatus 96 can be loaded into the film forming apparatus 97 without contact with oxygen in the atmosphere. Accordingly, it is possible to prevent a natural oxide film from adhering to the wafer W after the PHT processing, so that the film formation (the formation of the capacitor C) can be preferably performed.

Further, the structure of the substrate processed in the processing system 1 is not limited to that described in the above embodiment. Further, the etching implemented in the processing system 1 is not limited to that performed for the bottom portion of the contact hole H before the formation of the capacitor C as described in the embodiment, but the present invention is applicable to the removal processing of various silicon oxide films. The silicon oxide film that is the object to be subjected to etching in the processing system 1 is not limited to the BPSG film, but may be another kind of silicon oxide film, such as the HDP-SiO₂ film or the like. Also in this case, the depth where the reaction product becomes saturated, the etching amount and so on can be controlled by adjusting the temperature of the silicon oxide film and the partial pressure of the hydrogen fluoride gas in the mixed gas in the COR processing process according to the kind of the silicon oxide film. Especially, it is possible to increase the depth where the reaction product becomes saturated and improve the etching amount as compared to the etching method conventionally performed for the natural oxide film and the chemical oxide film.

Further, as for the CVD oxide film formed on the substrate, the kind of the CVD method used for the film formation of the CVD oxide film is not particularly limited. For example, the thermal CVD method, the atmospheric-pressure CVD method, the pressure-reduced CVD method, the plasma CVD method and so on may be used.

Further, the present invention is also applicable to etching of the silicon oxide film other than the CVD oxide films, for example, such as a natural oxide film, a chemical oxide film produced by chemical liquid treatment in the resist removal process or the like, a thermal oxide film formed by the thermal oxidization method and so on. Also in such silicon oxide films other than the CVD oxide film, the etching amount can be increased/decreased by adjusting the partial pressure of the hydrogen fluoride gas and the temperature of the silicon oxide film in the COR processing.

Even in the case where the wafer W is left standing for a long time, for example, after subjected to processing in the previous processing process (the resist removal process or the like) until the subsequent processing process (the film forming process) is performed with the result that a thick natural oxide film is formed on the wafer W, the removal process of the natural oxide film is performed by applying the present invention immediately before the subsequent processing process is performed, whereby the natural oxide film can be sufficiently removed. Accordingly, the waiting time after the previous processing process is finished until the removal process of the natural oxide film or the subsequent processing process is implemented can be extended. Therefore, it is possible to give freedom to a management time (Q-time).

It should be noted that the natural oxide film and other silicon oxide film (BPSG) such as the interlayer insulating film and so on exist on the wafer W in a mixed manner, and if it is desired to remove only the natural oxide film, it is only necessary to adjust the temperature of the wafer W to a lower value or the partial pressure of the hydrogen fluoride gas in the mixed gas to a lower value in the COR processing. For example, the temperature of the wafer W may be adjusted to about 30° C. or lower, or the partial pressure of the hydrogen fluoride gas in the mixed gas may be adjusted to about 15 mTorr (about 2.00 Pa) or lower. This makes it possible to efficiently alter the natural oxide film while suppressing the alteration of the other silicon oxide films such as the inter insulating film and so on. In short, the natural oxide film can be efficiently removed while suppressing damage to the other structure.

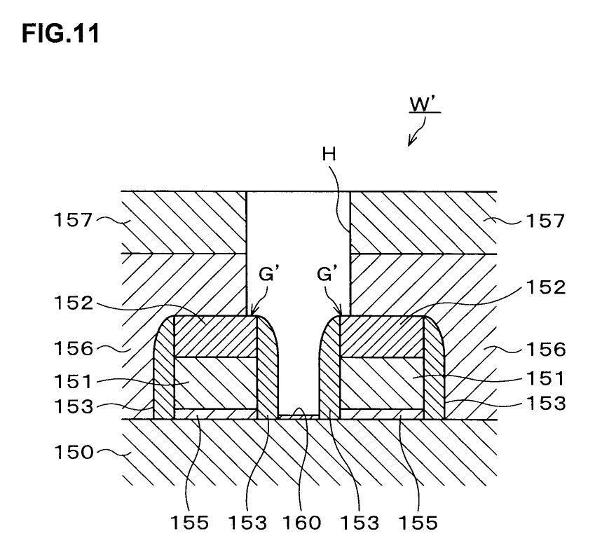

The structure in which the natural oxide film and other kinds of silicon oxide films and so on exist on the wafer in a mixed manner is, for example, as shown in FIG. 11. In FIG. 11, a Si layer 150 is formed on a front surface of a wafer W′, and two gate portions G′ having gate electrodes 151 are provided side by side on an upper surface of the Si layer 150. Each of the gate portions G′ includes a gate electrode 151 (SiO₂ layer), a hard mask (HM) layer 152 (SiN layer), and side wall portions (side walls) 153. More specifically, two SiO₂ films 155 being gate oxide films are formed on an upper surface of the Si layer 150, Poly-Si layers as the gate electrodes 151 are formed on upper surfaces of the SiO₂ films 155, respectively, and SiN layers (hard mask (HM) layers 152) are formed on upper surfaces of the Poly-Si layers (the gate electrodes 151) respectively. On both side surfaces of each of the SiO₂ films 155, the Poly-Si layers (the gate electrodes 151) and the SiN layers (the hard mask (HM) layers 152), the side wall portions 153 made of insulator are formed respectively. Further, a BPSG film 156 that is the interlayer insulating film is formed to cover these two gate portions G′, and a PE-SiO₂ film 157 is formed on an upper surface of the BPSG film 156. The PE-SiO₂ film 157 is a CVD silicon oxide film formed using the plasma CVD (PECVD: Plasma Enhanced CVD) method. Between the two gate portions G′ (between the side wall portions 153), a contact hole H is formed to penetrate the PE-SiO₂ film and the BPSG film 156. At a bottom portion of the contact hole H, the Si layer 150 is exposed, and a natural oxide film 160 is formed on the Si layer 150. In other words, in this structure, three kinds of silicon oxide films, that is, the natural oxide film 160, the BPSG film 156 and the PE-SiO₂ film 157 exist in a mixed manner. Also in the case where the natural oxide film 160 is removed from such a wafer W′, by appropriately adjusting the temperature of the wafer W′ and the partial pressure of the hydrogen fluoride gas in the mixed gas, the natural oxide film 160 can be selectively removed while suppressing the damage (CD shift) to the BPSG film 156 and the PE-SiO₂ film 157. Further, by adjusting the temperature of the wafer W′ and the partial pressure of the hydrogen fluoride gas in the mixed gas according to the thickness of the natural oxide film 160, even the natural oxide film 160 which has been left standing for a long time and thus formed thick can be surely removed. Note that in the formation (the film forming processing) of the capacitor performed on the wafer W′ after removal of the natural oxide film 160, the removal of the natural oxide film 160 from the Si layer 150 exposed at the bottom portion of the contact hole H allows a lower end portion of the capacitor to be surely connected to the Si layer 150.

### EXAMPLE

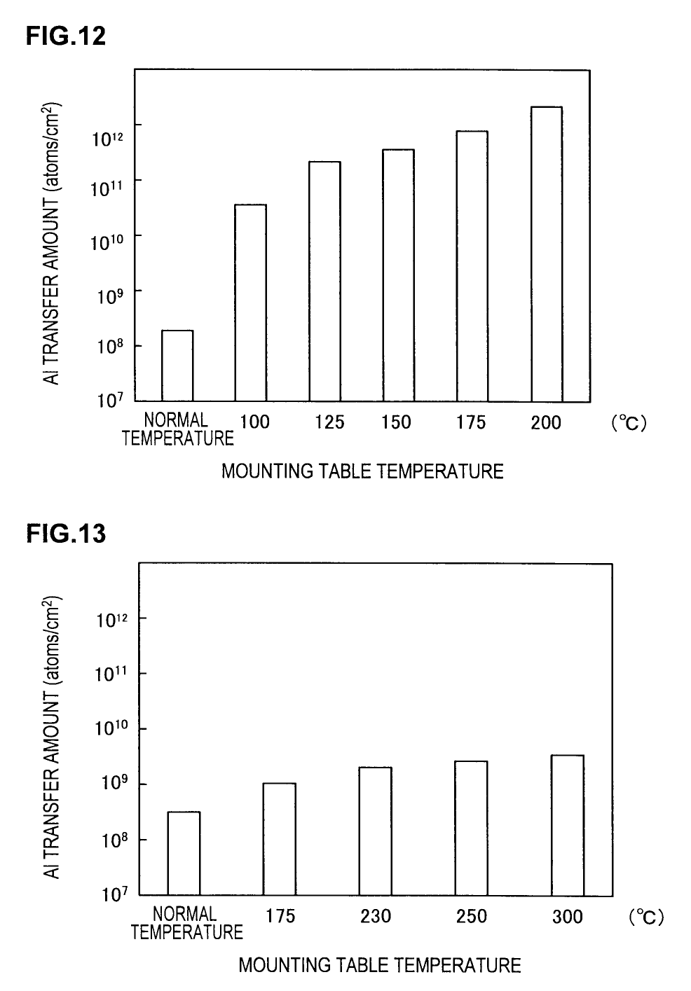

The aluminum transfer amounts to the wafer lower surface were compared between a case where the upper surface of the mounting table of the PHT apparatus was not covered by the cover (comparative example) and a case where the upper surface was covered by the cover (example). Note that the aluminum transfer amount was measured by ICP-Mass. In the case of the comparative example, when the temperature of the mounting table reached about 100° C., the aluminum transfer amount to the wafer lower surface exceeded 3×10¹⁰ atoms/cm², thus causing considerable metal contamination as shown in FIG. 12. On the other hand, in the case of the example, even when the temperature of the upper surface of the mounting table reached about 300° C., the aluminum transfer amount to the wafer lower surface was only about 5×10⁹ atoms/cm², resulting in negligible metal contamination as shown in FIG. 13.

What is claimed is:

1. A heat treatment apparatus for heat-treating a silicon substrate, comprising:
a mounting table for mounting and heating the silicon substrate thereon,
wherein a cover made of any of silicon, silicon carbide, and aluminum nitride is placed on an upper surface of said mounting table.

2. The heat treatment apparatus according to claim 1,
wherein said cover is disk-shaped and has a diameter larger than a diameter of the silicon substrate in a disk shape mounted on said mounting table.

3. The heat treatment apparatus according to claim 1,
wherein a plurality of support pins for supporting a lower surface of the silicon substrate are provided on an upper surface of said cover.

4. The heat treatment apparatus according to claim 1,
wherein recessed portions for receiving said plural support pins provided on the upper surface of said mounting table are provided in a lower surface of said cover.

5. The heat treatment apparatus according to claim 1,
wherein a reaction product film which is made by altering a silicon oxide film by chemical reaction with a mixed gas containing hydrogen fluoride gas and ammonia gas is formed on an upper surface of the silicon substrate.

6. A processing system for removing a silicon oxide film formed on an upper surface of a silicon substrate, comprising:
a COR apparatus for altering a silicon oxide film formed on the upper surface of the silicon substrate into a reaction product film by supplying a mixed gas containing hydrogen fluoride gas and ammonia gas to the upper surface of the silicon substrate; and the heat treatment apparatus according to claim 1.
